(19) United States
(12) Patent Application Publication
(10) Pub. No.: US 2025/0054874 A1
(43) Pub. Date: Feb. 13, 2025

(54) THREE-DIMENSIONAL SELF-REFERENCE MARKING FEATURES

(71) Applicant: INTERNATIONAL BUSINESS MACHINES CORPORATION, ARMONK, NY (US)

(72) Inventors: Daniel Piper, Vancouver, WA (US); Cynthia Manya, Poughkeepsie, NY (US); Yang Yang, Central Valley, NY (US); James John Demarest, Rensselaer, NY (US); Jonathan Fry, Fishkill, NY (US)

(21) Appl. No.: 18/447,287

(22) Filed: Aug. 9, 2023

(51) Int. Cl. H01L 23/544

(52) U.S. Cl. CPC H01L 23/544; H01L 2223/54433

(57) ABSTRACT

An apparatus and methodology for a back end of line (BEOL) structure in an integrated circuit (IC) die, includes a first BEOL structure layer having a first plurality of self-referential marking features disposed a first distance from a substrate of the IC die in a predefined two-dimensional (2D) arrangement. A second BEOL structure layer has a second plurality of the self-referential marking features a second distance from the substrate in a predefined 2D arrangement. The first and second pluralities of marking features collectively form a three-dimensional (3D) BEOL identifier (3D BEOL ID) self-referencing the IC die.

### BACKGROUND

The present disclosure generally relates to integrated circuit fabrication and, in particular, to product chips and die having a feature pattern built into the product during fabrication. The feature pattern provides a self-referencing code that can be used to obtain reliable information about the product chip in order to authenticate the product chip.

### SUMMARY

According to some embodiments of the present disclosure, a method is provided for fabricating a back end of line (BEOL) structure in an integrated circuit (IC) die. The method includes forming a first BEOL structure layer to include a first plurality of self-referential marking features. The first plurality of marking features is disposed a first distance from a substrate of the IC die in a predefined two-dimensional (2D) arrangement. The method further includes forming a second BEOL structure layer to include a second plurality of the self-referential marking features. The second plurality of marking features is disposed a second distance from the substrate in a predefined 2D arrangement. The first and second pluralities of marking features collectively form a three-dimensional (3D) BEOL identifier (3D BEOL ID) self-referencing the IC die.

In some embodiments, which may be combined with the preceding embodiment, a microelectronic device is provided that has a self-referential 3D BEOL ID. The 3D BEOL ID has a predefined arrangement of BEOL marking features that present a 2D node representation of the 3D BEOL ID as obtained from a first angular perspective, and that present a 3D code representation of the 3D BEOL ID as obtained from a second angular perspective.

In some embodiments, which may be combined with one or more preceding embodiments, a computer program product is provided for authenticating a device having a plurality of marking features in a predefined 3D arrangement that defines a self-referential code. The computer program product has a computer readable storage medium with program instructions embodied therewith. The program instructions are executable by a processor to cause a computing device to read a 2D image of the plurality of marking features obtained from a first angular perspective. The program instructions further cause the computing device to establish a 2D reference aligned to the first angular perspective, and to define nodes of the 3D arrangement of marking features from the 2D reference. The program instructions further cause the computing device to read a 3D image of the plurality of marking features obtained from a second angular perspective, and to transform the 2D reference to a 3D reference aligned to the second angular perspective. The program instructions further cause the computing device to decode the self-referential code in relation to nodal positions of the marking features relative to the 3D reference.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a functional block diagram illustration of a computer hardware platform that can communicate with various networked components.

FIG. 2 illustrates an example computer system architecture for efficiently authenticating an integrated circuit (“IC”) chip.

FIG. 3a diagrammatically depicts a semiconductor wafer.

FIGS. 3b-3k are cross-sectional depictions of the wafer of FIG. 3a during manufacture of self-reference marking features in accordance with illustrative embodiments of this technology.

FIG. 4a diagrammatically depicts scanning the IC die of FIG. 3k to obtain two-dimensional (“2D”) and three-dimensional (“3D”) images of the self-reference marking features after it has been singulated from the wafer of FIG. 3a and encased within an IC package.

FIG. 4b is a block diagram of the chip authentication engine in the computer system of FIG. 2, consistent with an illustrative embodiment.

FIG. 4c depicts steps in a method for authenticating an IC chip in accordance with illustrative embodiments of this technology.

FIG. 4d depicts the 2D image obtained from the scanning of FIG. 4a, consistent with an illustrative embodiment.

FIG. 4e depicts the 2D image of FIG. 4d with a 2D coordinate reference for the nodes.

FIG. 4f depicts the 2D coordinate reference of FIG. 4e after transformation to a 3D coordinate reference, consistent with an illustrative embodiment.

FIG. 4g depicts the 3D image obtained from the scanning of FIG. 4a, consistent with an illustrative embodiment.

FIG. 4h depicts the 3D coordinate reference of FIG. 4e aligned to the top boundary of the 3D image of FIG. 4f, consistent with an illustrative embodiment.

FIG. 4i depicts the 3D coordinate reference of FIG. 4e aligned to the bottom boundary of the 3D image of FIG. 4f, consistent with an illustrative embodiment.

FIG. 4j depicts the 3D coordinate reference of FIG. 4e aligned between the top layer marking features and the bottom layer marking features of the 3D image of FIG. 4f, consistent with an illustrative embodiment.

FIG. 4k depicts a node with both a top layer marking feature and a bottom layer marking feature, consistent with an illustrative embodiment.

FIG. 4l depicts a node with only a top layer marking feature, consistent with an illustrative embodiment.

FIG. 4m depicts a node with only a bottom layer marking feature, consistent with an illustrative embodiment.

FIG. 5 diagrammatically depicts indexing a database with the self-referencing 3D back-end-of-line (“BEOL”) identification (“ID”) (“3D BEOL ID”) in accordance with illustrative embodiments of this technology.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

To better understand the features of the present disclosure, it may be helpful to discuss known architectures. To that end, the following detailed description illustrates various aspects of the present disclosure by narrative text, flowcharts, block diagrams of computer systems and/or block diagrams of the image processing logic and machine learning logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

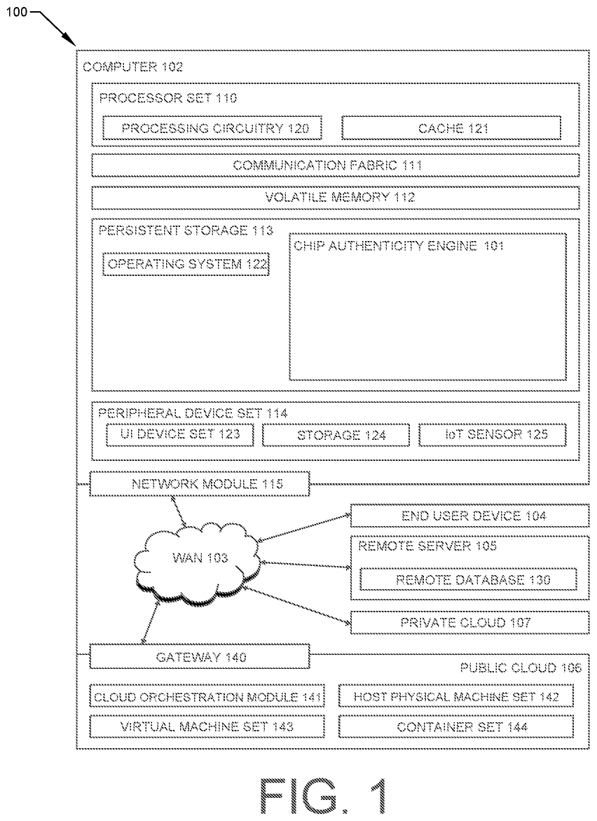

Referring to FIG. 1, computing environment 100 includes an example of an environment for the execution of at least some of the computer code involved in performing the inventive methods, including an integrated circuit (“IC”) chip authenticity engine block 101. In addition to block 101, computing environment 100 includes, for example, computer 102, wide area network (WAN) 103, end user device (EUD) 104, remote server 105, public cloud 106, and private cloud 107. In this embodiment, computer 102 includes processor set 110 (including processing circuitry 120 and cache 121), communication fabric 111, volatile memory 112, persistent storage 113 (including operating system 122 and block 101, as identified above), peripheral device set 114 (including user interface (UI) device set 123, storage 124, and Internet of Things (IoT) sensor set 125), and network module 115. Remote server 105 includes remote database 130. Public cloud 106 includes gateway 140, cloud orchestration module 141, host physical machine set 142, virtual machine set 143, and container set 144.

COMPUTER 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 102, to keep the presentation as simple as possible. Computer 102 may be located in a cloud, even though it is not shown in a cloud in FIG. 1. On the other hand, computer 102 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 102 to cause a series of operational steps to be performed by processor set 110 of computer 102 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 101 in persistent storage 113.

COMMUNICATION FABRIC 111 is the signal conduction path that allows the various components of computer 102 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 102, the volatile memory 112 is located in a single package and is internal to computer 102, but, alternatively or additionally, the volatile memory may be distributed over multiple packages and/or located externally with respect to computer 102.

PERSISTENT STORAGE 113 is any form of non-volatile storage for computers that is now known or to be developed in the future. The non-volatility of this storage means that the stored data is maintained regardless of whether power is being supplied to computer 102 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 101 typically includes at least some of the computer code involved in performing the inventive methods.

PERIPHERAL DEVICE SET 114 includes the set of peripheral devices of computer 102. Data communication connections between the peripheral devices and the other components of computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 102 is required to have a large amount of storage (for example, where computer 102 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 102 to communicate with other computers through WAN 103. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 102 from an external computer or external storage device through a network adapter card or network interface included in network module 115.

WAN 103 is any wide area network (for example, the internet) capable of communicating computer data over non-local distances by any technology for communicating computer data, now known or to be developed in the future. In some embodiments, the WAN 103 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 104 is any computer system that is used and controlled by an end user (for example, a customer of an enterprise that operates computer 102), and may take any of the forms discussed above in connection with computer 102. EUD 104 typically receives helpful and useful data from the operations of computer 102. For example, in a hypothetical case where computer 102 is designed to provide a recommendation to an end user, this recommendation would typically be communicated from network module 115 of computer 102 through WAN 103 to EUD 104. In this way, EUD 104 can display, or otherwise present, the recommendation to an end user. In some embodiments, EUD 104 may be a client device, such as thin client, heavy client, mainframe computer, desktop computer and so on.

REMOTE SERVER 105 is any computer system that serves at least some data and/or functionality to computer 102. Remote server 105 may be controlled and used by the same entity that operates computer 102. Remote server 105 represents the machine(s) that collect and store helpful and useful data for use by other computers, such as computer 102. For example, in a hypothetical case where computer 102 is designed and programmed to provide a recommendation based on historical data, then this historical data may be provided to computer 102 from remote database 130 of remote server 105.

PUBLIC CLOUD 106 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 106 is performed by the computer hardware and/or software of cloud orchestration module 141. The computing resources provided by public cloud 106 are typically implemented by virtual computing environments that run on various computers making up the computers of host physical machine set 142, which is the universe of physical computers in and/or available to public cloud 106. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 106 to communicate through WAN 103.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 107 is similar to public cloud 106, except that the computing resources are only available for use by a single enterprise. While private cloud 107 is depicted as being in communication with WAN 103, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 106 and private cloud 107 are both part of a larger hybrid cloud.

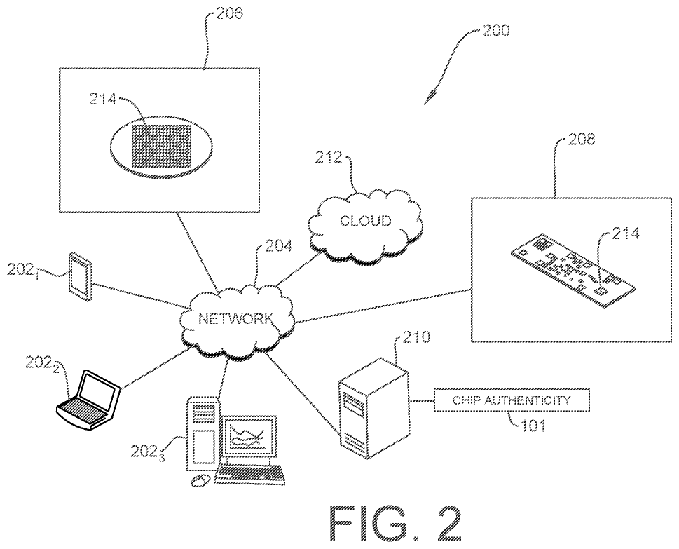

FIG. 2 depicts an illustrative computer system architecture for remotely communicating with other users via illustrative computer devices 202 in practicing advantageous embodiments of the IC chip authenticity engine 101. These computing devices 202 can include stationary computing devices such as desktop computers and enterprise computing systems, as well as portable computing devices such as laptop computers, portable handsets, smart-phones, tablet computers, personal digital assistants (“PDAs”), smart watches, and the like. These users have access to reliable information throughout a computer network 204 such as with a foundry 206 where IC dies are produced, and to a commercial manufacturer 208 where the IC chips are incorporated into industrial and consumer products such as the printed circuit board depicted. For example, a particular IC die 214 is depicted both in a wafer during manufacture at the foundry 206 and subsequently after being singulated from the wafer and included in finished goods by the manufacturer 208 as an IC packaged chip 214. The network access can also be provided to other remote users not depicted such as resellers, repairers, and the like.

The network 204 can be, but is not limited to, a local area network (“LAN”), a virtual private network (“VPN”), a cellular network, the Internet, combinations thereof, and the like. For example, the network 204 can include a mobile network that is communicatively coupled to a private network, sometimes referred to as an intranet that provides various ancillary services, such as communication with various application stores, libraries, and the Internet. The network 204 enables the chip authenticity engine 101, which is a software program running on the server 210, to communicate with data produced and/or requested from the computing devices 202, providers of goods and services 206, 208, and the cloud 212 to carry out IC chip authentication in accordance with these illustrative embodiments.

The server 210 can process the information via resources available to it, such as image processing resources and machine learning resources. The phrase “machine learning” broadly describes a function of an electronic system that learns from data. A machine learning system, engine, or module can include a trainable machine learning algorithm that can be trained, such as in an external cloud environment, to learn functional relationships between inputs and outputs that are currently unknown.

Machine learning can be utilized to solve a variety of technical issues (e.g., learning previously unknown functional relationships) in connection with technologies such as, but not limited to, machine learning technologies, time-series data technologies, data analysis technologies, data classification technologies, data clustering technologies, trajectory/journey analysis technologies, medical device technologies, collaborative filtering technologies, recommendation system technologies, signal processing technologies, word embedding technologies, topic model technologies, image processing technologies, video processing technologies, audio processing technologies, and/or other digital technologies.

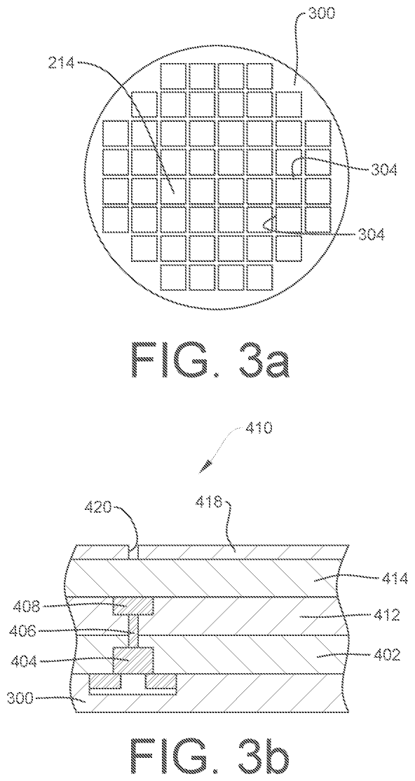

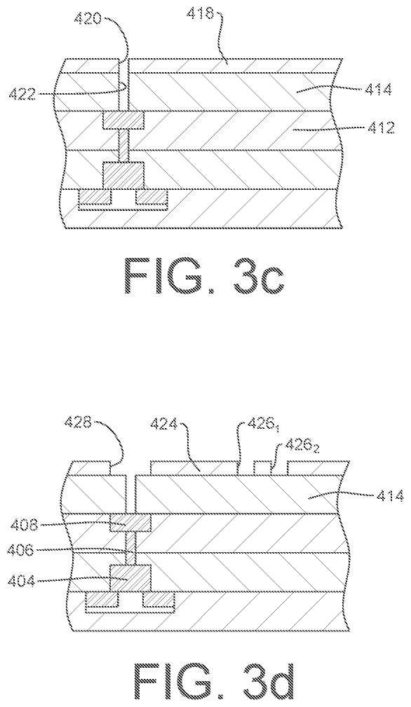

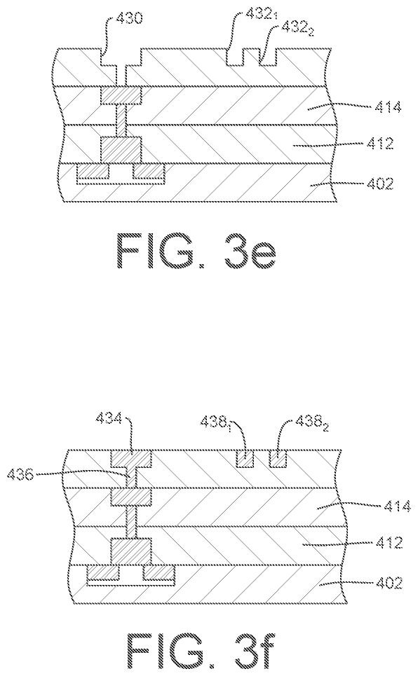

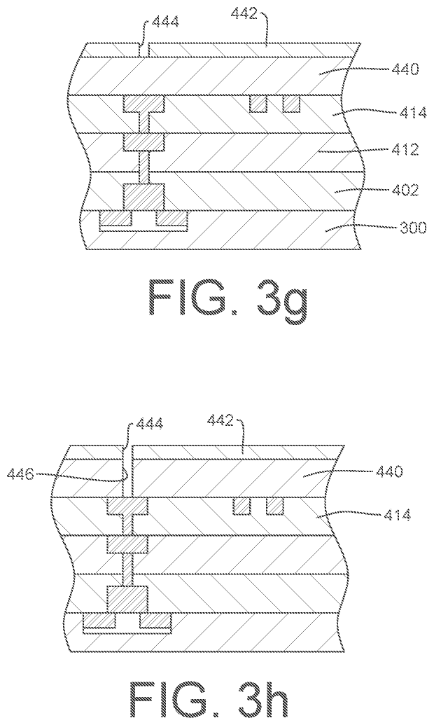

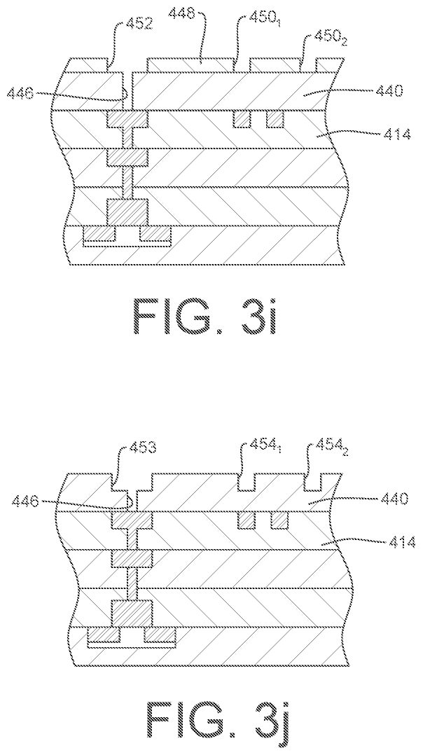

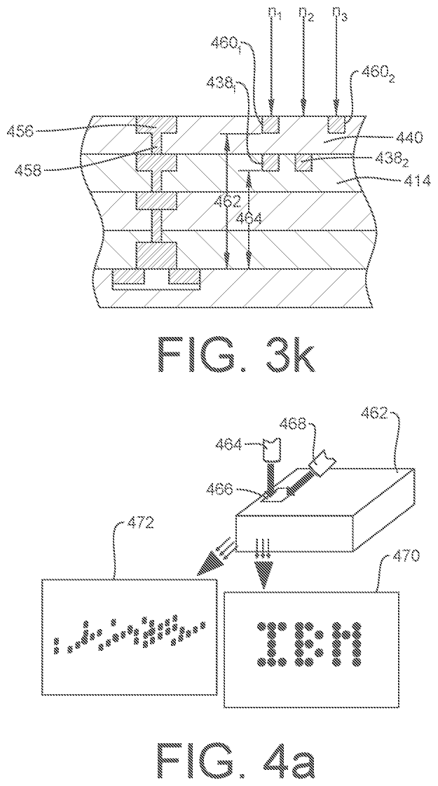

With reference to FIG. 3a and in accordance with illustrative embodiments of this technology, a semiconductor wafer 300 is depicted as would be manufactured in the foundry 206 of FIG. 2. The wafer 300 has been processed by front-end-of-line (“FEOL”) processes to fabricate an array of IC dies 214. Each IC die 214 has integrated circuitry that can contain semiconductor devices, such as the illustrative transistor depicted in FIGS. 3b-3k. The arrayed rows and columns of IC dies 214 can range in numbers from tens to tens of thousands of individual IC dies. Round wafers as depicted typically have diameters within a range of about 100 millimeters (“mm”) to 300 mm. The number depends on many factors, namely the individual IC die 214 size and the wafer 300 size. Scribe-line channels 304 are created between adjacent rows and columns, which are free of semiconductor devices but can contain test devices for gathering information about the wafer 300 and the IC dies 214, crack lines, and other like items extraneous to the workings of the IC dies.

Wafer 300 can be any suitable semiconductor material that a skilled artisan recognizes to be suitable for forming an IC. For example, the wafer 300 can be composed of a monocrystalline silicon-containing material, such as bulk or SOI single crystal silicon. The semiconductor material can be doped with an impurity to alter its electrical properties. For instance, the wafer 300 can be doped with an n-type impurity to render it initially n-type, or doped with a p-type impurity to render it initially p-type.

Turning now to several cross sectional diagrammatic depictions of an IC die manufacturing process, FIG. 3b depicts a first dielectric layer 402 formed on the wafer 300. The wafer 300 provides a substrate for this and the subsequent layers and devices making up the IC die circuitry. A transistor 404 has been formed partially in the wafer 300 and partially in the first dielectric layer 402. Metalized electrical connectors 406 and wire traces 408 are embedded in this and the overlying dielectric layers, which are commonly referred to as the back-end-of-line (“BEOL”) circuitry structure denoted by reference number 410. Typically, there can be several (e.g., two to ten or any other suitable number) such dielectric layers collectively forming the BEOL 410. These dielectric layers 402, 412, 414 are formed by lithographic and etching techniques that are generally described in the following.

An etch stop layer (not depicted) and then the dielectric layer 414 are applied to the top surface of the dielectric layer 412. These layers can be produced by conventional deposition techniques that are widely known and well recognized to the skilled artisan. The etch stop layer caps the underlying dielectric layer 412, and can be formed from any material that etches selectively to the dielectric material forming the dielectric layer 412. Typical materials can be a thin film of silicon nitride, silicon carbonitride, silicon oxycarbonitride, or silicon carbide deposited by, for example, plasma enhanced chemical vapor deposition.

The dielectric layer 414 can be any suitable organic or inorganic dielectric material such as, but not limited to, silicon dioxide, fluorine-doped silicon glass, and combinations of these dielectric materials. Alternatively, the dielectric layer 414 can be characterized by a relative permittivity or dielectric constant smaller than the dielectric constant of silicon dioxide, which is about 3.9. Candidate low-k dielectric materials for the dielectric layer 414 include, but are not limited to, porous and nonporous spun-on organic low-k dielectrics, such as spun-on aromatic thermoset polymer resins like polyarylenes, porous and nonporous inorganic low-k dielectrics, such as organosilicate glasses, hydrogen-enriched silicon oxycarbide, carbon-doped oxides, and combinations of these and other organic and inorganic dielectrics. If the dielectric layer 414 is composed of a low-k dielectric material, the physical and material properties of the etch stop layer can be adjusted to operate as a barrier film that optimizes resist poisoning characteristics. Dielectric layer 414 can be deposited by any number of well known conventional techniques such as sputtering, spin-on application, chemical vapor deposition (“CVD”) process or a plasma enhanced chemical vapor deposition process (“PECVD”).

With continued reference to FIG. 3b, a resist layer 418 composed of a radiation-sensitive organic material is applied as a thin film to a top surface of the dielectric layer 414, such as by spin coating. The resist layer 418 is pre-baked, exposed to radiation to impart a latent image of a via pattern, baked, and then developed with a chemical developer. The chemical developer removes nonpolymerized material to transform the latent image of the via pattern in the resist layer 418 into a final image pattern. The final image pattern imparted in the resist layer 418 includes openings 420 exposing the dielectric layer 414 beneath. Procedures for applying and lithographically patterning the resist layer 418 using a photomask and lithography tool are known to the skilled artisan. Alternatively, a hardmask (not depicted) can be applied to the dielectric layer 414 before the resist layer 418. In subsequent patterning steps, the hardmask is etched in conjunction with the resist layer 418, which is removed after patterning the hardmask. The hardmask then serves as the primary mask for the etching process.

FIG. 3c depicts a via 422 is created in the dielectric layer 414 extending to the etch stop layer above the dielectric layer 412. The portion of the dielectric layer 414 not masked by the resist layer 418 is removed with an etching process, such as reactive ion etching (“RIE”), which is capable of producing substantially vertical sidewalls for the via 422. After penetrating through the dielectric layer 414, the etch stop layer halts the vertical progress of the etching process so that the underlying metallization in lower dielectric layer 412 is not etched. After etching the via 422, the residual resist layer 418 is removed such as with a wet chemical stripper or a dry oxidation-based photoresist removal technique, like plasma ashing with an oxygen plasma.

FIG. 3d depicts another resist layer 424 composed of a radiation-sensitive organic material can then be applied such as with a spin coating process to the dielectric layer 414. Resist layer 424 is composed of a positive photoresist that, when unexposed, is initially insoluble in a photoresist developer. As understood by the skilled artisan, the portion of the positive photoresist in resist layer 424 that is exposed to radiation during the lithography process loses chemical stability and, as a result, becomes soluble to a photoresist developer. The portion of the positive photoresist in resist layer 424 that is unexposed to radiation during the lithography process remains chemically stable and, therefore, retains its insolubility when exposed to photoresist developer. The resist layer 424 originates from a liquid resist solution containing a resist resin dissolved in a solvent.

An adhesion promoter, such as hexamethyldisilazane, can be initially applied on the dielectric layer 414 to promote adhesion of the resist layer 424. The spin coating process entails placing the wafer 300 on a spin coater, dispensing the liquid resist solution onto the top surface of the dielectric layer 414, and operating the spin coater to rapidly spin the wafer 300. Spinning disperses the liquid resist solution supplied to the center of the wafer 300 radially outward by centrifugal forces to coat the entire top surface and to provide the resist layer 424 with a nominally uniform thickness throughout. A typical spin coating process runs at a speed range of about 1,000 to 5,000 revolutions per minute (“rpm”) for about one minute or less and results in a physical layer thickness between about 0.5 microns and about 2.5 microns. The resist layer 424 is then heated in a soft baking or pre-baking process to drive off excess solvent and to promote partial solidification.

The soft-baked resist layer 424 is then exposed to a pattern of radiation to impart a latent image of a trench pattern. For optical lithography, the pattern of radiation is generated using a photomask and an optical stepper of a lithography tool and then imaged onto the resist layer 424. Regions of the resist layer 424 exposed to the radiation become chemically less stable. Regions of the resist layer 424 that are not exposed to the radiation remain chemically stable. This chemical modification of the exposed regions of the resist layer 424 permits subsequent removal by contact with a chemical developer.

Openings 426 through the resist layer 424 can be provided in a peripheral region of the BEOL wiring structure 410 bordering one of the scribe-line channels. Device structures, such as the transistor 404, connector 406, and wire trace 408, are not fabricated in this peripheral region. This is typically an unused surface area of the wafer 300. The peripheral region can be outside of the image field of the mask used to form the latent image of the trench pattern. If this is the case, then the openings 426 can be produced by other processes such as direct write e-beam lithography, LCD-variable masking, gray scale lithography, and the like.

The term “peripheral,” for purposes of this description and meaning of the appended claims, means that in these illustrative embodiments the marking features (such as 438ᵢ, 460ᵢ) formed in openings like the openings 426 do not function as electrical components of the BEOL wiring structure. In some embodiments not depicted the marking features can be formed above or below electrical components in the BEOL wiring structure.

In any event, the resist layer 424 can be subjected to a post-exposure bake process before the developing process. The elevated temperature of the post-exposure bake process drives photoproduct diffusion in the resist layer 424, minimizes the negative effects of standing waves in the resist layer 424, and drives acid-catalyzed reactions in chemically amplified positive resists. The resist layer 424 is then developed with the use of a developer to transform the latent image into a final image pattern with an opening 428 and the openings 426. Portions of the dielectric layer 414 not masked by the resist layer 424 are exposed to a developer, such as can be delivered on a spin coater in a manner similar to the delivery of the resist solution. An exemplary developer that can be used to develop positive photoresist is an alkali developing liquid, such as tetramethylammonium hydroxide, itself or in solution with a surfactant. The resulting resist layer 424 is then subjected to a hard-baking process, which solidifies the residual photoresist of the patterned resist layer 424 to increase durability and robustness.

FIG. 3e depicts trenches 430, 432 formed by removing regions of the dielectric layer 414 that are not masked by the resist layer 424, such as with anisotropic etching like an RIE process. The directional etching process is capable of producing substantially vertical sidewalls, extending partially through the dielectric layer 414 in these illustrative embodiments. The resist layer 424 can then be removed such as with a wet chemical stripper or a dry oxidation-based photoresist removal technique. Liner layers (not depicted) can be applied in the trenches 430, 432, using, for example, any conductive material or multilayer combination of conductive materials such as tantalum, tantalum nitride, titanium, titanium nitride, tungsten, ruthenium, iridium, rhodium, platinum, chromium, niobium, or another suitable conductor with material properties appropriate to operate as a diffusion barrier and an adhesion promoter for a subsequent metal plating process. The liner layers can be deposited, for example, by conventional deposition processes, including but not limited to a physical vapor deposition (“PVD”) process, ionized-PVD (“iPVD”), ALD, plasma-assisted ALD, CVD, and PECVD.

FIG. 3f depicts a metallized wire 434, connector 436, and marking features 438 are formed in the respective openings formed in the dielectric layer 414. This metallization can be produced with any appropriate electrically conductive material such as copper, aluminum, copper-aluminum alloys, tungsten, and other similar metals. The conductive material is deposited as a blanket layer by conventional deposition processes, such as CVD, PECVD, an electrochemical process such as electroplating or electroless plating, chemical solution deposition, PVD, DC or RF sputtering, and the like. A thin seed layer (not shown) may be deposited inside the trenches 430, 432 to promote the deposition process. After the blanket deposition, portions of the conductive material can overfill the trenches 430, 432 and cover the dielectric layer 414. In that event, a chemical-mechanical polishing (“CMP”) process can be employed to remove the excess conductive material and to planarize the dielectric layer's 414 top surface.

FIGS. 3g-3k that follow depict a substantially similar process as above for producing the next dielectric layer 440 on top of the dielectric layer 414. Beginning with FIG. 3g, as in the description above of FIG. 3b, an etch stop layer (not depicted) and then the next dielectric layer 440 are applied to the top surface of the dielectric layer 414. A resist layer 442 is applied to the dielectric layer 440. The resist layer 442 is pre-baked, exposed to radiation to impart a latent image of a via pattern, baked, and then developed with a chemical developer. The final image pattern imparted in the resist layer 442 includes an opening 444 exposing the dielectric layer 440 beneath.

Like the description of FIG. 3c above, FIG. 3h depicts a via 446 is created in the dielectric layer 440 extending to the etch stop layer above the dielectric layer 414. After etching the via 446, the residual resist layer 442 is removed.

Like the description of FIG. 3d above, FIG. 3i depicts another resist layer 448 is applied to the dielectric layer 440. The resist layer 448 is then heated in a soft baking or pre-baking process to drive off excess solvent and to promote partial solidification. The soft-baked resist layer 448 is then exposed to a pattern of radiation to impart a latent image of a trench pattern. Openings 450 in the BEOL wiring structure 410, if need be, can be produced by other processes such as direct write e-beam lithography, LCD-variable masking, gray scale lithography, and the like. In any event, the resist layer 448 can then be baked and then developed to transform the latent image into a final image pattern with an opening 452 and the openings 450. The resulting resist layer 448 can then be subjected to a hard-baking process, which solidifies the residual photoresist of the patterned resist layer 448 to increase durability and robustness.

Like the description of FIG. 3e above, FIG. 3j depicts trenches 453, 454 are formed by removing regions of the dielectric layer 440 that are not masked by the resist layer 448, and the resist layer 448 is then removed. Liner layers (not depicted) can be applied in the trenches 453, 454. Finally, as described above for FIG. 3f, FIG. 3k depicts a metallized wire 456, connector 458, and marking features 460 are formed in the respective trenches formed in the dielectric layer 440.

Staying with FIG. 3k, the dielectric layer 440 is thus formed to include a pair of the marking features 460₁, 460₂ that are equally spaced from the wafer 300, or substrate, a distance 462. They are in a two-dimensional plane that is parallel to the plane of the substrate 300. Likewise, the underlying dielectric layer 414 is formed to include another pair of the marking features 438₁, 438₂ in another 2D plane that is parallel to the plane of the substrate 300, spaced apart a distance 464. In these illustrative embodiments there are a number of other marking features 438ᵢ, 460ᵢ in those parallel 2D planes but at other cross sections of the IC die 214. The layers 414, 440 can be formed to include them as well in the same way described above but at other cross sections of the 2D planes.

The predefined arrangement of these marking features 438ᵢ, 460ᵢ intentionally places one or more of them at each of a number of nodes of a three-dimensional self-referencing identifier code (“3D BEOL ID”) in the IC die 214. For instance, FIG. 3k depicts at this particular cross section there are three such nodes, nᵢ. At the left node n₁ there is both a top-layer marking feature 460₁ and a bottom-layer marking feature 438₁. At the middle node n₂ there is only a bottom-layer marking feature 438₂. At the right node n₃ there is only a top-layer marking feature 460₂. The distinctively different patterns of these marking features are leveraged for purposes of encoding individual digits of the 3D BEOL ID. For example, without limitation, these illustrative embodiments assign the code digit value of “2” to nodes (such as n₁) having both a top-layer marking feature (such as 460₁) and a bottom-layer marking feature (such as 438₁). The code digit value of “0” is assigned to nodes (such as n₂) having only a bottom-layer marking feature (such as 438₂). The code digit value of “1” is assigned to nodes (such as n₃) having only a top-layer marking feature (such as 460₂). The self-referential 3D BEOL ID is defined by concatenating the code digit values in a predetermined number of nodes. For example, in the example below a nine-digit 3D BEOL ID is decoded as 201020102.

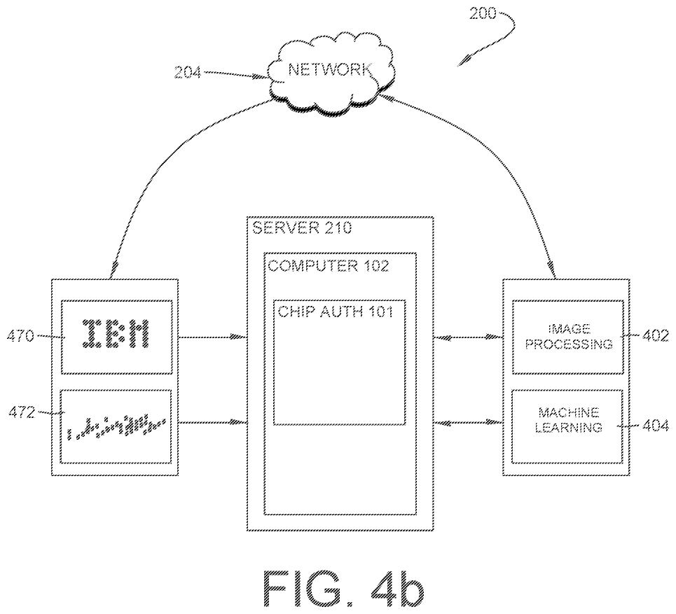

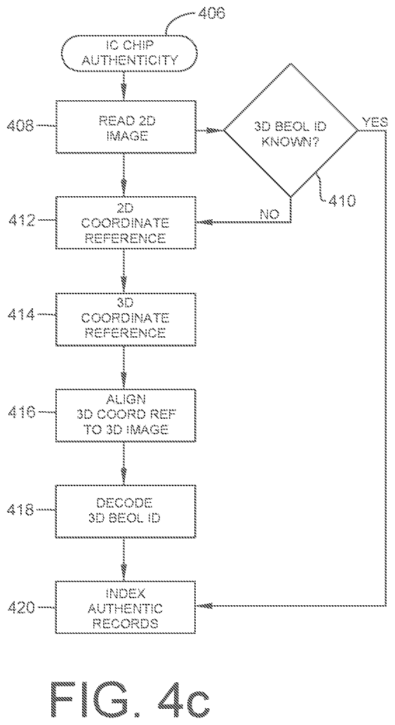

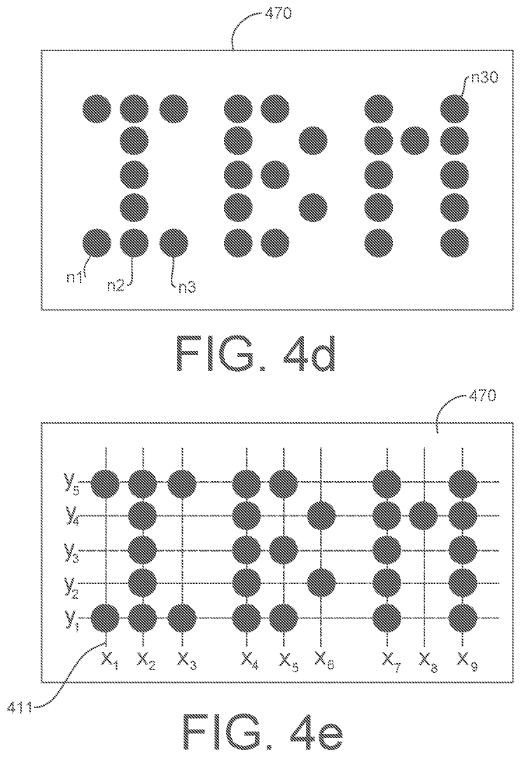

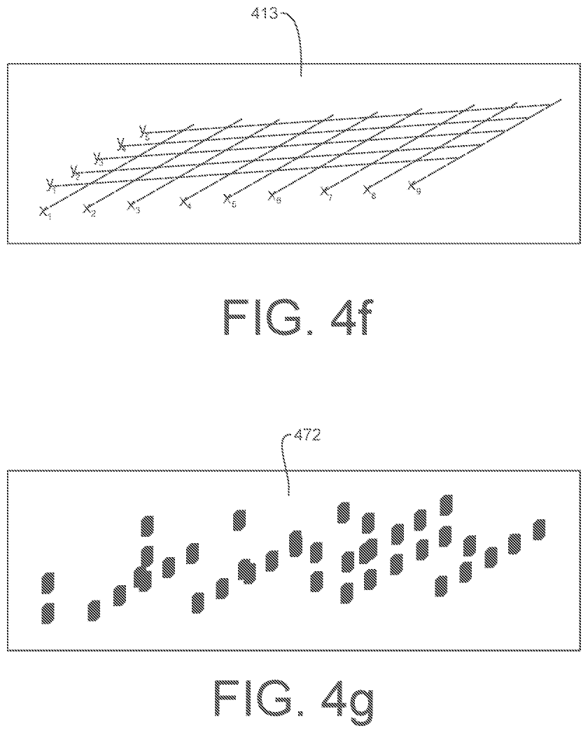

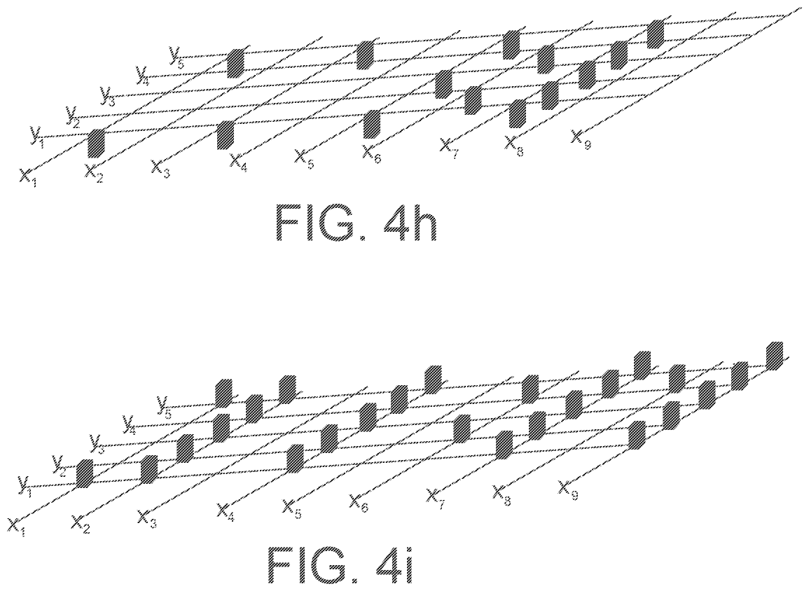

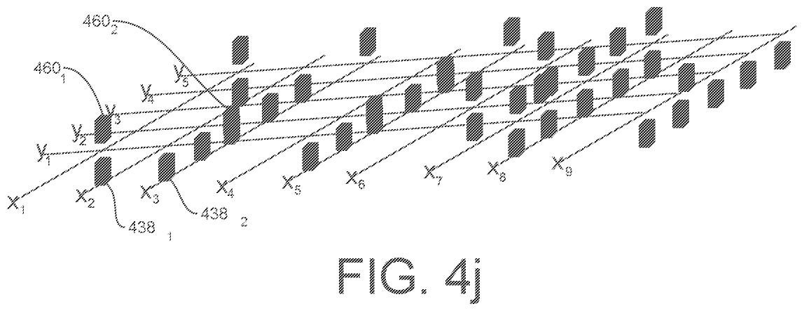

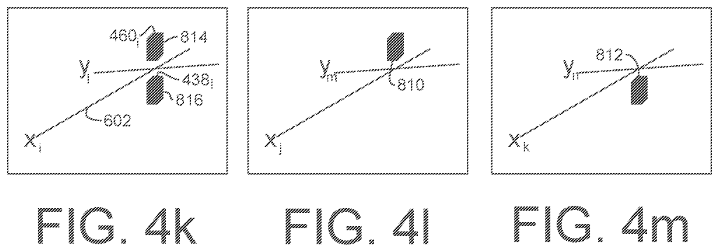

Reference now is made to FIG. 4a, which diagrammatically depicts the IC die 214 with a self-referential 3D BEOL ID after having been singulated from the wafer 300 and encased in an IC die package 462. To decode the 3D BEOL ID, a scan 464 is done of the IC die package 462, and in turn the IC die 214 inside it, in a substantially vertical direction and with a selected type of energy waveform beam. The contemplated scope of this technology is not limited to scanning with any particular type of energy waveform. A second scan 468 with the same or a different waveform energy is done at a different angular orientation.

The marking features (such as 438, 460) in the IC die 214, collectively forming the 3D BEOL ID, are detectable by their wave reflection patterns in responses to the scans 464, 468. Signal processing techniques can analyze and condition raw images by employing gray-scale variation to pulse amplitude, reflected peak amplitude, time of flight, phase inversion, and the like. Electromagnetic radiation x-rays are well suited for use in that they nondestructively penetrate the IC die package 462 to read the arrangement of the marking features. Alternatively, other forms of penetrating electromagnetic beam energy can be used such as infrared radiation, terahertz radiation, and acoustic beam energy. In alternative embodiments at least one of the scans 464, 468 can employ energy beams in the visible or near visible light spectrum, or charge coupled device (CCD) cameras, and the like. FIG. 4a depicts a window 466 can be provided in the IC package 462 for that purpose. The scans 464, 468 produce a 2D scan image 470 and a 3D scan image 472 of the plurality of marking features (such as 438, 460) making up the 3D BEOL ID. The scan images 470, 472 can be transmitted and or displayed throughout the system network 204 (FIG. 2).

FIG. 4b is a conceptual block diagram of the computer system architecture 200 of FIG. 2 for IC chip authentication, consistent with illustrative embodiments. In this nonlimiting example, the system 200 has allocated processing resources to authenticate the scanned images 470, 472 of FIG. 4a. The chip authenticity engine 101 can be programmed to have top-level control as to whether to use image processing resources 402 and/or machine learning resources 404 to do so. After decoding the 3D BEOL ID, the chip authenticity engine 101 can use the 3D BEOL ID code to access stored information about the IC die 214 and thereby report on authenticity to all those with credentials to receive the information throughout the system network 204.

FIG. 4c is a flowchart depicting steps in a method 406 that the chip authenticity engine 101 can be programmed to perform to authenticate the IC die 214 in these illustrative embodiments. In block 408 the 2D image 470 is read and, and in block 410 it can be determined whether the corresponding 3D BEOL ID is already known. This can be done efficiently by querying one or more learning machines that are trained in converting 2D images to corresponding 3D BEOL IDs. If a trained learning machine successfully decodes the 3D BEOL ID from the 2D image 470, then the system authentication request can be fulfilled entirely with machine learning resources 404. However, there will be times when the up-to-date learning machines can falter, such as when they have not previously been trained on the 2D image 470.

If the 3D BEOL ID is unknown for the 2D image 470, then control can pass to block 412 for image processing steps on the 2D image 470, which is enlarged in FIG. 4d. This 2D image indicates there are 30 nodes used to form three letters “I” and “B” and “M” for purposes of this illustrative example. As mentioned previously, this gives the indication that for each of these 30 nodes there is some type of marking feature configuration. Each node might have both a top-layer and a bottom layer marking feature (bit code=2), or just a bottom-layer marking feature (bit code=0), or just a top-layer marking feature (bit code=1).

FIG. 4e depicts the method 406, in block 412, having constructed a 2D coordinate reference 411 for spatially mapping these 30 nodes to the following coordinate locations:

{x1, y1}; {x1, y5}
{x2, y1}; {x2, y2}; {x2, y3}; {x2, y4}; {x2, y5}
{x3, y1}; {x3, y5}
{x4, y1}; {x4, y2}; {x4, y3}; {x4, y4}; {x4, y5}
{x5, y1}; {x5, y3}; {x5, y5}
{x6, y2}; {x6, y4}
{x7, y1}; {x7, y2}; {x7, y3}; {x7, y4}; {x7, y5}
{x8, y4}
{x9, y1}; {x9, y2}; {x9, y3}; {x9, y4}; {x9, y5}

In block 414 the 2D coordinate reference 411 is transformed into 3D space to align it with the oblique angle of the second scan 468 (FIG. 4a). An exemplary transformed reference 413 is depicted in FIG. 4f. It defines locations of the same nodes n1, n2, n3 . . . n30 as in the 2D image of FIG. 4e, but in a 3D plane that is parallel to the dielectric layers 414, 440 in the IC die 214 (FIG. 3k) and hence parallel to the 2D planes of the top-layer marking features (such as 460) and the bottom-layer marking features (such as 438).

The transformed coordinate reference 413 makes it possible to identify locations of the marking features in the 3D image 472, which is enlarged in FIG. 4g. Referring momentarily to the cross section in FIG. 3k, note that the 3D image 472 represents a finite vertical thickness of the IC die 214 between the top ends of the top-layer marking features (such as 460) and the bottom ends of the bottom-layer marking features (such as 438). Optical imaging processes such as edge finding techniques can be employed to virtually align the transformed coordinate reference 413 relative to the 3D image 472.

For example, without limitation, in block 416 the computer method can align the transformed coordinate reference 413 at an upper boundary with top ends of the top-layer marking features (such as 460ᵢ), as depicted in FIG. 4h. Similarly, the transformed coordinate reference 413 can be virtually located to the lower boundary, aligned with the bottom ends of the bottom-layer marking features (such as 438ᵢ), as depicted in FIG. 4i. Knowing the upper and lower boundary locations, the transformed coordinate reference 413 can then be located in the space between the upper-layer marking features (such as 460ᵢ) and the bottom-layer marking features (such as 438ᵢ) by splitting the difference of the boundary conditions. This virtually puts the transformed coordinate reference 413 passing through the dielectric layer 440, between the bottom ends of the top-layer marking features (such as 460ᵢ) and the top ends of the bottom-layer marking features (such as 438ᵢ), as depicted in FIG. 4j.

With the transformed reference 413 positioned between the top-layer marking features (such as 460ᵢ) and the bottom-layer marking features (such as 438ᵢ), decoding the 3D image 472 begins in block 418 by further optical processing to determine what marking features are located at the 30 previously-identified node locations. This can be accomplished in some areas of the 3D image with high probability, especially in the outermost regions. There are some image collisions, however, complicating the detection of marking features in the 3D image 472. To remedy that, schema rules can be employed for 3D BEOL ID coding that provide probabilistic solutions to image collisions. For example, without limitation, in these illustrative embodiments it will be assumed a coding rule exists stating that any particular bit code is the same for all nodes located along the same x-axis of the transformed reference 413. Thus, if the marking feature at the xᵢ, yⱼ node is ascertainable with a high degree of probability, but the marking feature at the xᵢ, yₖ node is not ascertainable due to image collision, then the image processing can be programmed to assign the xᵢ bit code in terms of the unobstructed detections at the xᵢ, yⱼ node. Decoding proceeds by comparing the detected image at the 30 previously identified nodes to each of the three possible marking feature configurations. The programming instructions can compare nodal images to the theoretically constructed images depicted in FIGS. 4k-4m. FIG. 4k depicts the node located at xᵢ, yₗ is assigned a code bit value=2 because there is both a top-level marking feature 460ᵢ and a bottom-layer marking feature 438ᵢ there. The image processing can detect this configuration in terms that an edge 810 (FIG. 4l) is detected above the reference axis 413 and another edge 812 (FIG. 4m) is detected below the reference axis 413. Detecting parallel side edges 814, 816 is another possibility for detecting this marking feature configuration. In contrast, FIG. 4l depicts the node located at xⱼ, yₘ is assigned a code bit value=1 because there is only a top-level marking feature 460ᵢ there. The image processing can detect this configuration in terms that the edge 810 is detected above the reference axis 413 but not below. Finally, FIG. 4m depicts the node located at xₖ, yₙ is assigned a code bit=0 because there is only a bottom-level marking feature 438ᵢ there, such as determined by only detecting the edge 812 below the reference axis 413.

The decoding can begin with any of the nodes, such as for the two defined nodes along the x₁ axis at x₁, y₁ and at x₁, y₅. Note that the x₁, y₁ node happens to have the top-layer marking feature 460₁ and the bottom-layer marking feature 438₁ depicted in FIG. 3k. Both of the nodal images are free of image collision, both the top edge 810 and the bottom edge 812 at both nodes are unobstructed. Thus, there is a high probability that image detection will correctly declare the code bit value=2 for the x₁ axis.

Next, consideration is given to the x₂ axis and its five previously identified nodes at x₂, y₁ and x₂, y₂ and x₂, y₃ and x₂, y₄ and x₂, y₅. Bottom edges 812 only are clearly detectable at the y₁, y₂, y₄ and y₅ nodes. Programming instructions can leverage the governing rule of consistency that says all code bit configurations are the same for any given xi, causing the image processing computer to declare the code bit value=0 along the x₂ axis with a high degree of probability, disregarding the image collision at the y₃ node.

Next, consideration is given to the x₃ axis and its two previously identified nodes at x₃, y₁ and at x₃, y₅. Image processing computer instructions can further improve processing efficiency by selecting to process the unobstructed x₃, y₅ node first and thus avoid the image collision at x₁, y₁. Analysis of the unobstructed x₃, y₅ node detects only the top edge 810, such that the code bit value=1 can be declared for x₃ with high probability.

Next, consideration is given to the x₄ axis and its five previously identified nodes at all y locations. Only bottom edges 812 are detectable on unobstructed images at each of the y₁, y₂ and y₄ nodes. This would be sufficient for the programming instructions to declare the code bit value=0 for the x₄ axis with high probability, disregarding the image collisions at the y₃ and y₅ nodes.

Next, consideration is given to the x axis and its three previously identified nodes at x₅, y₁ and at x₅, y₃, and at x₅, y₅. Only edge 810 is clearly detectable on the unobstructed nodal image at x₅, y₅. This would be sufficient for the programming instructions to declare the code bit value=1 for the x₅ axis, disregarding the image collisions at the other two nodes.

Next, consideration is given to the x₆ axis and its two previously identified nodes at x₆, y₂ and at x₆, y₄. Both top edge 810 and bottom edge 812 are clearly detectable on the unobstructed image at the x₆, y₂ node. This would be sufficient for the programming instructions to declare the code bit value=2 for the x₆ axis with high probability, disregarding the image collision at the x₆, y₄ node.

Next, consideration is given to the x₇ axis and its five previously identified nodes at all y locations. Both top edge 810 and bottom edge 812 are clearly detectable on unobstructed images at each of the y₁, y₃, y₄ and y₅ nodes. This would be sufficient for the programming instructions to declare the code bit value=2 for the x₇ axis, disregarding the image collision at the y₂ node.

Next, consideration is given to the x₈ axis and its one previously identified node at x₈, y₄. Only bottom edge 812 is clearly detectable on the unobstructed image at that location. This would be sufficient for the programming instructions to declare the code bit value=0 for the x₈ axis with high probability.

Next, consideration is given to the x₉ axis and its five previously identified nodes at all y locations. Only bottom edges 812 are clearly detectable on all five unobstructed images. This would be sufficient for the programming instructions to declare the code bit value=0 for the x₉ axis with high probability.

Thus, by these computer programming instructions the chip authentication engine 101, with allocated machine learning and image processing resources, would be able to decode the 3D BEOL ID by concatenating the nine code bits:

| | x AXIS NODES | | | | | | | | |
|---|---|---|---|---|---|---|---|---|---|
| | x₁ | x₂ | x₃ | x₄ | x₅ | x₆ | x₇ | x₈ | x₉ |
| 3D BEOL ID CODE BIT | 2 | 0 | 1 | 0 | 1 | 2 | 2 | 0 | 0 |

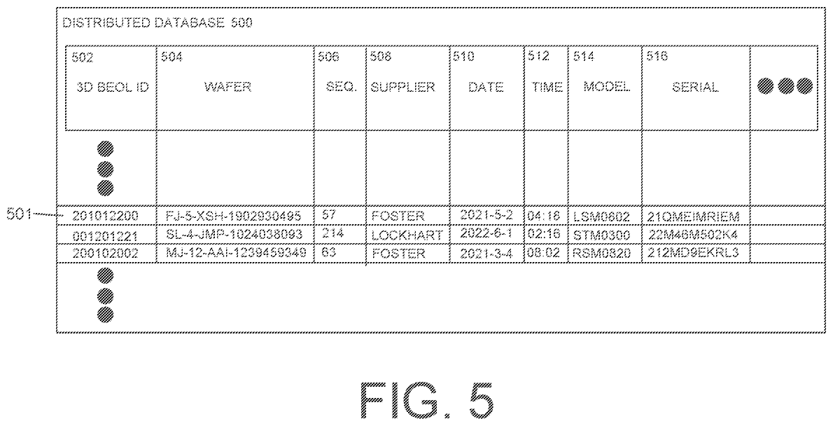

Having decoded the 3D BEOL ID, it can then be used to authenticate the IC chip 214 by indexing reliable information about the authentic IC chip known to bear the decoded 3D BEOL ID. For example, without limitation, FIG. 5 diagrammatically depicts a computer database 500 that is accessible either locally or via the system network 204. It is constructed to include the 3D BEOL ID 502 as a searchable index value. By indexing this stored information by the 3D BEOL ID 501, the chip authenticity engine 101 is able to authenticate the IC die 214 in terms of any desirable records such as a wafer record 504, a wafer location record 506, a supplier record 508, a fabrication date 510 and time 512, a model number 514, a serial number 516, and the like.

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to call flow illustrations and/or block diagrams of a method, apparatus (systems), and computer program products according to embodiments of the present disclosure. It will be understood that each step of the flowchart illustrations and/or block diagrams, and combinations of blocks in the call flow illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the call flow process and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the call flow and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the call flow process and/or block diagram block or blocks.

The flowchart and block diagrams in the Figures illustrate the architecture, functionality, and operation of possible implementations of systems, methods, and computer program products according to various embodiments of the present disclosure. In this regard, each block in the call flow process or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or call flow illustration, and combinations of blocks in the block diagrams and/or call flow illustration, can be implemented by special purpose hardware-based systems that perform the specified functions or acts or carry out combinations of special purpose hardware and computer instructions.

It is to be appreciated that the computer system 200 (e.g., the specialized computer 102, the chip authenticity engine 101, the image processing resources 502, and/or the machine learning resources 504) performs acts on the 2D image 470 and the 3D image 472 that cannot be performed by a human (e.g., is greater than the capability of a single human mind). For example, an amount of image data processed, a speed of processing of image data and/or data types of the data processed over a certain period of time can be greater, faster and different than an amount, speed and data type that can be processed by a single human mind over the same period of time. The computer system can also be fully operational towards performing one or more other functions while also performing the above-referenced conditioning of the time series data for purposes of machine learning. Moreover, image processing and machine learning outputs generated by computer system 200 can include information that is impossible to obtain manually by a user. For example, an amount of information included in the image processing and machine learning outputs and/or a variety of information included in the image processing and machine learning outputs can be more complex than information obtained manually by a user.

Moreover, because at least transforming the coordinate reference and applying it to the 3D image 472 is established from a combination of electrical and mechanical components and circuitry, a human is unable to replicate or perform processing performed by the computer system (e.g., specialized computer 102, chip authenticity engine 101) disclosed herein. For example, a human is unable to physically validate parallelism of the virtually transformed coordinate reference at each and every nodal inquiry during decoding steps.

Additionally, the specialized computer 102 significantly improves the operating efficiencies of the computer system by probabilistic schema rules and computations that ensure high probabilities and remove the adverse variations stemming from human judgments. Transmitting images 470, 472 and the decoded 3D BEOL ID from any and all authorized network clients as disclosed herein intentionally and significantly eliminates the need to transmit large volumes of data that is of no effect in ultimately authenticating the IC die 214. This frees up computer system 200 processing overhead and storage capacities to attend to more important processes, generally reducing the overall cost of machine learning.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A microelectronic device having a self-referential three dimensional (3D) back end of line (BEOL) identification (ID) comprising a predefined arrangement of BEOL marking features that present a 2D node representation of the 3D BEOL ID as obtained from a first angular perspective and that present a 3D code representation of the 3D BEOL ID as obtained from a second angular perspective.

2. The microelectronic device of claim 1, further comprising:
a first BEOL structure layer spaced a first distance from a substrate and having a first plurality of the BEOL marking features in the predefined arrangement of BEOL marking features; and
a second BEOL structure layer spaced a second distance from the substrate and having a second plurality of the BEOL marking features in the predefined arrangement of BEOL marking features.

3. The microelectronic device of claim 2, wherein the first plurality of BEOL marking features are disposed within a first 2D plane, and the second plurality of BEOL marking features are disposed in a second 2D plane that is parallel to the first 2D plane.

4. A computer program product for authenticating a device having a plurality of marking features in a predefined 3D arrangement that defines a self-referential code, the computer program product comprising a computer readable storage medium having program instructions embodied therewith, the program instructions executable by a processor to cause a computing device to:
read a 2D image of the plurality of marking features obtained from a first angular perspective;
establish a 2D reference aligned to the first angular perspective;
define nodes of the 3D arrangement of marking features from the 2D reference;
read a 3D image of the plurality of marking features obtained from a second angular perspective;
transform the 2D reference to a 3D reference aligned to the second angular perspective; and
decode the self-referential code in relation to nodal positions of the marking features relative to the 3D reference.

5. The computer program product of claim 4, wherein:
the plurality of marking features includes a first set in a first 2D plane and a second set in a second 2D plane that is parallel to the first 2D plane; and
the executed programming instructions cause the computing device to virtually align the 3D reference to be parallel to the first and second planes.

6. The computer program product of claim 5, wherein the programming instructions cause the computing device to virtually align the 3D reference in a space between the first and second planes.

7. The computer program product of claim 6, wherein the programming instructions cause the computing device to decode the self-referential code in relation to detecting whether a marking feature in the first set and a marking feature in the second set exist at a node of the 3D reference.

8. A method of fabricating a back end of line (BEOL) structure in an integrated circuit (IC) die, comprising:
forming a first BEOL structure layer to include a first plurality of self-referential marking features disposed a first distance from a substrate of the IC die in a predefined two-dimensional (2D) arrangement; and
forming a second BEOL structure layer to include a second plurality of the self-referential marking features a second distance from the substrate in a predefined 2D arrangement, the first and second pluralities of marking features collectively forming a three-dimensional (3D) BEOL identifier (3D BEOL ID) self-referencing the IC die.

9. The method of claim 8, further comprising:
storing information related to the IC die in a computer memory; and
indexing the computer memory with the 3D BEOL ID to recall the stored information from the computer memory.

10. The method of claim 9, wherein the substrate is a portion of a wafer also forming other substrates for other IC dice.

11. The method of claim 10, wherein the stored information includes at least one of a wafer record, a location of the substrate in the wafer, an entity record, a date, a time, a manufacturing record, or an IC die record.

12. The method of claim 8, wherein at least one of the first and second layers is a dielectric layer.

13. The method of claim 8, further comprising forming at least one of the first and second marking features by forming an opening in at least one of the first and second layers and placing a marker material in the opening.

14. The method of claim 8, further comprising:
reading a 2D image of the plurality of marking features obtained from a first angular perspective;
establishing a 2D reference aligned to the first angular perspective; and
defining nodes of the 3D arrangement of marking features from the 2D reference.

15. The method of claim 14, further comprising:
reading a 3D image of the plurality of marking features obtained from a second angular perspective;
transforming the 2D reference to a 3D reference aligned to the second angular perspective; and
decoding the 3D BEOL ID in relation to nodal positions of the marking features relative to the 3D reference.

16. The method of claim 15, wherein the second angular perspective comprises an oblique representation of the 3D arrangement of marking features.

17. The method of claim 15, wherein:
the substrate is a portion of an IC wafer; and
before the reading the first and second images, singulating the IC die from the IC wafer.

18. The method of claim 15, further comprising, before the reading the first and second images, encasing the IC die in an IC die package.

19. The method of claim 15, further comprising reading at least one of the first and second images by electromagnetic radiation.

20. The method of claim 15, further comprising reading at least one of the first and second images through a window in the IC die package.
